(19) United States
(12) Patent Application Publication
(10) Pub. No.: US 2006/0005771 A1
(43) Pub. Date: Jan. 12, 2006

(54) Apparatus and method of shaping profiles of large-area PECVD electrodes

(75) Inventors: John M. White, Hayward, CA (US); Emanuel Beer, San Jose, CA (US); Wei Chang, Los Altos, CA (US); Robin L. Tiner, Santa Cruz, CA (US); Soo Young Choi, Fremont, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/143,506

(22) Filed: Jun. 2, 2005

Related U.S. Application Data
(60) Provisional application No. 60/587,173, filed on Jul. 12, 2004.

(51) Int. Cl. C23C 16/00; C23F 1/00

(52) U.S. Cl. 118/728; 156/345.51; 118/723 R

(57) ABSTRACT

An apparatus and method for shaping profiles of a large-area PECVD electrode is provided. A plasma-enhanced CVD chamber for processing a large-area substrate is first provided. The chamber includes a lower electrode that supports a large area substrate. The lower electrode is shaped to selectively conform the supported substrate in a selected orientation under operating conditions. The orientation may be either planar or nonplanar. The substrate complies with the shape of the electrode so the substrate is substantially parallel to an upper electrode in the chamber, and/or to a gas diffusion plate in the chamber. The lower electrode comprises a substrate support fabricated from a material of insufficient strength to support itself at operating temperatures and pressure in the chamber. The shape of the substrate support is adjusted by modifying the dimensions and/or planarity of a supporting base structure, and/or by appropriately varying the thickness of the substrate support.

### CROSS REFERENCE TO RELATED APPLICATIONS

This application claims priority to U.S. Provisional Patent Application No. 60/587,173, filed Jul. 12, 2004.

### BACKGROUND OF THE INVENTION

1. Field of the Invention

Embodiments of the present invention generally relate to substrate processing methods, such as methods for processing flat-panel displays. Embodiments of the present invention also generally relate to a processing apparatus for processing flat panel displays. In addition, the invention relates to a plasma-enhanced CVD processing chamber.

2. Description of the Related Art

Flat panel displays are commonly used for computer screens, television monitors, cell phone displays, personal digital assistants, and other electronic equipment. Flat panel displays employ an active matrix of electronic devices, such as thin film transistors, or TFT's. The electronic devices are conventionally made on large flat substrates referred to as flat panel substrates. Generally, flat panel substrates are made of two thin plates of glass or, in some instances, a polymeric material. A layer of liquid crystal material is sandwiched between the thin plates. At least one of the plates includes a conductive film that is adapted to couple to a power source. Power supplied to the conductive film from the power source selectively changes the orientation of the crystal material, thereby creating a pattern display.

In order to manufacture these displays, a substrate is subjected to a plurality of sequential processes to create electronic devices on the substrate. Such devices may be conductors, insulators or thin film transistors (TFT's). Each of the processes is generally conducted in a process chamber adapted to perform a single step of the production process. In order to efficiently complete the entire sequence of processing steps, a number of process chambers are typically coupled to a central transfer chamber that houses a robot to facilitate transfer of the substrate between the process chambers. A processing platform having this configuration is generally known as a cluster tool, examples of which are the families of AKT plasma enhanced chemical vapor deposing (PECVD) processing platforms available from AKT America, Inc., which is a wholly owned division of Applied Materials, Inc., located in Santa Clara, Calif.

Various deposition techniques are known for placing a film onto large-area flat substrates. Chemical vapor deposition is commonly used to deposit thin films. In some instances, plasma-enhanced chemical vapor deposition, or “plasma enhanced CVD,” is employed. Plasma-enhanced CVD techniques promote excitation and/or dissociation of reactant gases by the application of radio-frequency (RF) energy. RF energy is directed to a reaction zone near the substrate surface, thereby creating a plasma. The high reactivity of the species in the plasma reduces the energy required for a chemical reaction to take place, and thus lowers the temperature required for CVD processes as compared to conventional thermal CVD processes.

For plasma-enhanced CVD, a parallel plate plasma reactor may be used. Parallel plate plasma reactors utilize opposing electrodes to form the plasma in a reaction zone between the two electrodes. In this respect, an RF bias voltage power level is applied to the electrodes in the processing chamber. One of the electrodes may be a substrate support and the other may be a gas diffusion plate. Parallel plate plasma reactors are available from AKT which manufactures various processing platforms for processing large-area flat substrates. Such substrates may be used to make thin film transistor liquid crystal diode (TFT-LCD) displays for flat panel televisions and for other TFT devices.

With the marketplace's acceptance of flat panel technology, the demand for larger displays, increased production and lower manufacturing costs has driven equipment manufacturers to develop new systems that accommodate larger size flat substrates. These larger flat substrates may also be used to form a greater number of smaller area displays on one substrate that may lower production costs per display. Previous generation large-area substrates were processed in sizes of about 550 mm×650 mm. However, current large-area substrates may be as large as 1800 mm×2200 mm or larger.

As flat substrate size increases, the electrodes that are used to produce the plasma are scaled to greater dimensions. Larger sizes can produce non-uniformities in the deposition properties of the plasma which may degrade display quality. For example, when a large-area flat substrate is placed on a heated substrate support, which may also function as one electrode in the chamber, the flat substrate may tend to deform during heating and deposition. Deformation of the flat substrate may generally include failure of the substrate to maintain a planar, flat profile on the substrate support, such as bowing. This deformation of the substrate may cause small amounts of gas to become trapped between the substrate and the substrate support, which can adversely affect the uniformity of the plasma and the deposition on the substrate. In addition, deformation of the substrate may cause a lack of uniform contact between the substrate support and the supported substrate. In these instances, good physical contact between the substrate and the substrate support may be lost, or may never even be obtained. Lack of good physical contact with the substrate support may affect the uniformity of the deposition process.

In some instances, fatiguing of the substrate support and supported substrate may cause the substrate to lose a desired orientation to the orientation of a gas diffusion plate, upper electrode, or a gas diffusion plate that also functions as a lower electrode. The upper electrode or the gas diffusion plate that forms the upper border of the reaction zone may be substantially planar or nonplanar. In such instances, the operator may desire to be able to control the profile of the substrate relative the upper electrode or gas diffusion plate.

A substrate support that resists deflection during high temperature processing was disclosed in commonly assigned U.S. Pat. No. 6,554,907. However, it is further desirable to provide a plasma-enhanced CVD chamber wherein the substrate support is selectively shaped before processing begins. Pre-shaping of the substrate support, in turn, allows the supported glass to be shaped into or out of planar orientation, as desired.

### SUMMARY OF THE INVENTION

The present invention generally relates to a semiconductor processing apparatus. More specifically, the invention relates to a plasma-enhanced CVD chamber for processing large-area flat substrates made of glass, polymers, or other suitable substrate material capable of having electronic devices formed thereon.

A plasma-enhanced chemical vapor deposition (PECVD) chamber for processing a large-area flat substrate is first provided. The chamber includes an upper electrode and a lower electrode. The lower electrode supports the flat substrate. The lower electrode comprises a substrate support and a base structure. In one embodiment, the substrate support is fabricated from a material that has insufficient strength to rigidly support itself in a desired orientation under typical operating conditions such as low pressure and high temperature. The base structure is fabricated from a material that has sufficient strength to rigidly support itself and the substrate support during operating conditions. The base structure is pre-shaped to reinforce the substrate support in a desired orientation within the chamber. The substrate support may be fabricated from a thermally conductive metal such as aluminum and may have at least one heating element disposed therein.

In one embodiment, the substrate support is reinforced by a lattice-type base structure which may include at least one base plate oriented in a first direction, and at least two lateral support plates disposed on the at least one base plate. The lateral support plates are preferably oriented generally transverse to the at least one base plate. The base structure is preferably fabricated from a material that has sufficient strength to rigidly support itself under typical operating temperature and pressure conditions, for example, a ceramic material.

In one embodiment, the base structure is preshaped in a nonplanar shape. The foundational base structure may be preshaped to reinforce the substrate support in a parallel orientation relative to a nonplanar upper electrode. Alternatively, the base structure may be preshaped to reinforce the substrate support in a parallel orientation relative to a nonplanar gas diffusion plate, or showerhead, within the chamber.

In yet another embodiment, a desired shaping of the electrode is created by varying the thickness of the substrate support itself. For example, the upper electrode may be concave in shape. It is therefore desirable to shape the substrate by using a supporting substrate support that is convex so as to provide a more parallel orientation between the upper electrode and the flat substrate. Similarly, a gas diffusion plate may be provided in the chamber that is concave in shape. It is therefore desirable to shape the substrate by using a substrate support that is convex so as to provide a parallel orientation between the showerhead and the flat substrate.

In one arrangement, the upper electrode and the showerhead may both be planar. However, the substrate support and supported flat substrate may tend to bow into the base structure, forming a convex shape. To provide a planar shape to the substrate support and supported flat substrate under typical operating conditions, the thickness of the substrate support may be appropriately varied. Alternatively, the thickness of the base structure may be appropriately varied. In one embodiment, shims may be selectively placed on a top surface of the lattice-type base structure to compensate for “bowing” of the substrate support and the flat substrate thereon.

In another embodiment, a plasma-enhanced chemical vapor deposition (PECVD) chamber for processing a large-area flat substrate is provided. The chamber has an upper electrode, a substrate support assembly disposed below the upper electrode and supporting the flat substrate, a lower electrode within the substrate support assembly, a processing region formed between the upper and lower electrodes, a gas inlet, and a diffusion plate for delivering gases into the processing region. The lower electrode is pre-shaped in accordance with the various descriptions provided above to selectively conform the supported flat substrate in a nonplanar manner under operating temperature conditions.

A substrate support assembly for supporting a large-area glass substrate in a plasma-enhanced chemical vapor deposition (PECVD) chamber is also provided. In one arrangement, the substrate support assembly first includes a substrate support fabricated from a thermally conductive metal and serving as a lower electrode. The substrate support is fabricated from a material having insufficient strength to support itself under operating conditions. In one embodiment, the substrate support has an appropriately varied thickness to offset anticipated thermally induced planarity changes during substrate processing. In addition, the substrate support assembly includes a base structure for supporting the substrate support. Preferably, the base structure is a lattice-type structure that includes at least one ceramic base plate oriented in a first direction, and at least two ceramic support plates disposed on the at least one base plate and oriented generally transverse to the at least one base plate. Each of the ceramic support plates may have at least one shim disposed on a top surface to offset the nonplanar response of the substrate support under operating conditions. Preferably, the base structure has sufficient strength to rigidly support itself under operating conditions.

A method for shaping an electrode in a plasma-enhanced chemical vapor deposition (PECVD) chamber is also provided. The method includes the step of providing an upper electrode in the chamber, and also providing a substrate support fabricated from a thermally conductive metal. The substrate support is configured to receive a large-area flat substrate and to serve as a lower electrode in the chamber. The substrate support is fabricated from a thermally conductive metal of insufficient strength to rigidly support itself under operating conditions. The method also includes the step of providing a base structure for reinforcing the substrate support. In one aspect, shims are provided on top of the base structure to overcome anticipated nonplanar response of the substrate support under operating conditions.

In one embodiment of the method, the substrate support has a variable thickness to provide a nonplanar shape to the substrate support before being exposed to operating temperature conditions. For example, the substrate support may be concave before being placed on the base structure and substantially planar after being placed on the base structure under operating temperature conditions. In one aspect, the substrate support bows into a substantially planar shape when supported by the base structure under operating temperature conditions. In another aspect, the substrate support bows into a convex shape when supported by the base structure under operating temperature conditions. This step is beneficial where, for example, the upper electrode and/or the upper gas diffusion plate in the chamber is concave. Thus, a parallel orientation is provided between (1) the substrate support and supported large-area substrate, and (2) the upper electrode and/or the upper gas diffusion plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only selected embodiments of this invention and are not to be considered limiting of its scope, for the invention may admit to other equally effective embodiments.

FIG. 1 is a side, cross-sectional view of a substrate processing chamber.

FIG. 2 is an exploded perspective view of a substrate support assembly, in one embodiment.

FIG. 3 is a plan view of the substrate support of FIG. 2.

FIG. 4 is a front view of the substrate support assembly of FIG. 2.

FIG. 5 is a side view of the substrate support assembly of FIG. 2.

FIG. 6 is a bottom view of the substrate support assembly of FIG. 2.

FIG. 7 is an alternate embodiment of a substrate support for the substrate support assembly.

FIG. 8 is an alternate embodiment of a lattice-type support structure for the substrate support assembly.

FIG. 9 is a side, cross-sectional view of a substrate processing chamber in an alternate embodiment.

### DETAILED DESCRIPTION OF THE PREFERRED EMBODIMENT

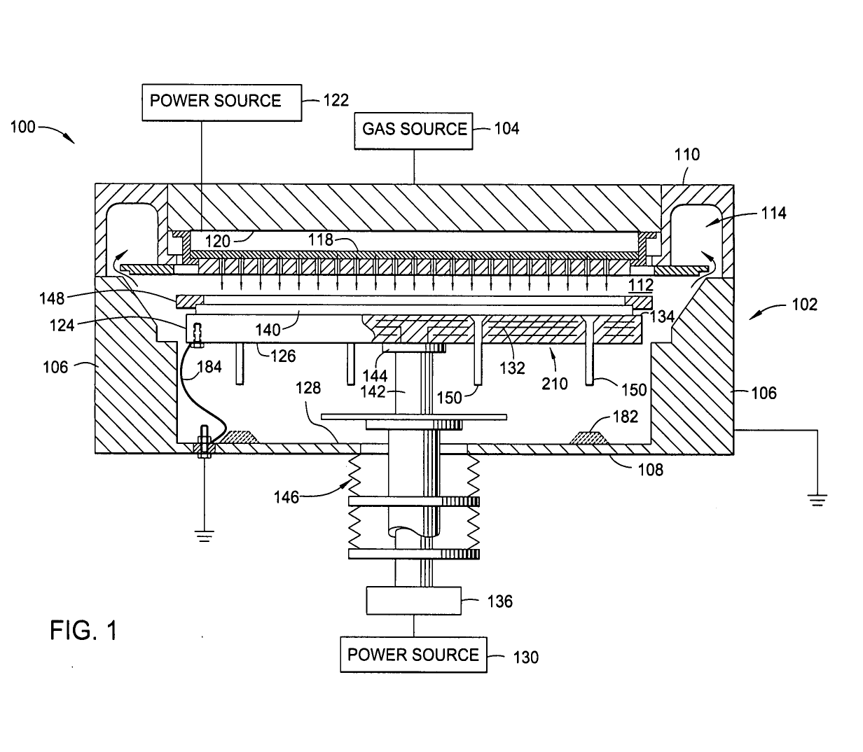

FIG. 1 is a side, cross-sectional view of one embodiment of a substrate processing chamber 100. The processing chamber 100 is configured to receive a large-area flat substrate 140, and to provide plasma-enhanced chemical vapor deposition on the substrate 140. For purposes of this disclosure, the term “large-area substrate” refers to a substrate having a cross-sectional area of about 1.0 meters² or larger. In addition, for purposes of this disclosure, the term “plasma-enhanced chemical vapor deposition” (PECVD) refers to any chamber used in the processing of a large area substrate including a plasma etching chamber, a chemical vapor deposition (“CVD”) chamber, a rinse chamber, or other known chamber. In addition, the chamber 100 may be a stand-alone chamber, an in-line chamber, a cluster tool chamber, or some combination or variation thereof.

The chamber 100 includes a grounded chamber body 102 coupled to a gas source 104 and a power source 122. The chamber body 102 has sidewalls 106, a bottom 108, and a lid assembly 110 that define a processing region 112. The processing region 112 is typically accessed through a gate or port (not shown) in the sidewall 106 that facilitates movement of a large area substrate 140 into and out of the chamber body 102. The sidewalls 106 and bottom 108 of the chamber body 102 are typically fabricated from aluminum or other material compatible with process chemistries. The lid assembly 110 contains a pumping plenum 114 that couples the processing region 112 to an exhaust port that is coupled to various pumping components (not shown).

The lid assembly 110 is supported by the sidewalls 106 and can be removed to service the chamber body 102. The lid assembly 110 is generally comprised of aluminum. A gas distribution plate 118 is coupled to an interior side 120 of the lid assembly 110, or to the sidewalls 106. The distribution plate 118 is typically fabricated from aluminum and includes a center portion having a perforated area through which process and other gases supplied from the gas source 104 are delivered to the processing region 112. The perforated area of the gas distribution plate 118 is configured to provide a uniform distribution of gases passing through the distribution plate 118 into the chamber body 102. The power source 122 is coupled to the distribution plate 118 to provide an electrical bias that energizes the process gas to ignite and sustain a plasma formed from process gas in the processing region 112 below the gas distribution plate 118 during processing.

A substrate support assembly 210 is centrally disposed within the chamber body 102. The substrate support assembly 210 supports the substrate 140 during processing and may include a support body 124 supported by a shaft 142 that extends through the chamber bottom 108. The support body 124 is generally polygonal in shape and covered with an electrically insulative coating (not shown) over at least the portion of the support body 124 that supports the substrate 140. The coating may also cover other portions of the support body 124. Optionally, the substrate support assembly 210 may be coupled to ground at least during processing by one or more RF ground return paths 184 that provide a low-impedance RF return path between the substrate support assembly 210 and ground. In one embodiment, the RF ground return path 184 is a plurality of flexible straps (one of which is shown in FIG. 1) coupled between a perimeter of the support body 124 and the chamber bottom 108.

The support body 124 may be fabricated from metals or other comparably electrically conductive materials. The insulative coating may be a dielectric material such as an oxide, silicon nitride, silicon dioxide, aluminum dioxide, tantalum pentoxide, silicon carbide or polyimide, among others, which may be applied by various deposition or coating processes, including, but not limited to, flame spraying, plasma spraying, high energy coating, chemical vapor deposition, spraying, adhesive film, sputtering and encapsulating.

In one embodiment, the substrate support assembly 210 includes a support body 124 made of aluminum and has at least one embedded heating element 132 and a thermocouple (not shown). The heating element 132 may be an electrode or resistive element and is coupled to a power source 130 to controllably heat the substrate support assembly 210 and substrate 140 positioned thereon to a predetermined temperature. Typically, the heating element 132 maintains the substrate 140 at a uniform temperature of about 150° Celsius to at least about 460° Celsius during processing. The support body 124 may include one or more stiffening members (not shown) comprised of metal, ceramic or other stiffening materials embedded therein.

Generally, the substrate support assembly 210 has a lower side 126 and an upper surface 134 that supports the substrate 140 thereon. The lower side 126 has a stem cover 144 coupled thereto. The stem cover 144 generally is an aluminum ring coupled to the substrate support assembly 210 that provides a mounting surface for the attachment of the shaft 142 thereto.

Generally, the shaft 142 extends from the stem cover 144 through the chamber bottom 108 and couples the substrate support assembly 210 to a lift system 136 that moves the substrate support assembly 210 between an elevated process position (as shown) and a lowered position that facilitates substrate transfer. A bellows 146 provides a vacuum seal between the chamber body 102 and the lift system 136 while facilitating the vertical movement of the substrate support assembly 210. The shaft 142 additionally provides a conduit for electrical and thermocouple leads between the substrate support assembly 210 and other components of the chamber 100.

The shaft 142 may be electrically isolated from the chamber body 102 by a dielectric isolator 128 disposed between the shaft 142 and chamber body 102. The isolator 128 may additionally support or be configured to function as a bearing for the shaft 142.

The substrate support assembly 210 optionally supports a shadow frame 148 configured to avoid deposition on the portion of the substrate support assembly 210 not covered by the substrate 140. Alternatively or additionally, the shadow frame 148 may be configured to avoid deposition on the edge of the substrate 140 and the substrate support assembly 210. Both configurations are contemplated to reduce sticking of the substrate 140 to the substrate support assembly 210.

The substrate support assembly 210 has a plurality of holes disposed therethrough that accept corresponding lift pins 150. The lift pins 150 are typically fabricated from ceramic or anodized aluminum, and have first ends that are substantially flush with or slightly recessed from the upper surface 134 of the substrate support assembly 210 when the lift pins 150 are retracted relative to the substrate support assembly 210. As the substrate support assembly 210 is lowered to a transfer position, the lift pins 150 come into contact with the bottom 108 of the chamber body 102 and are displaced through the substrate support assembly 210 to project from the upper surface 134 of the substrate support assembly 210, thereby placing the substrate 140 in a spaced-apart relation to the substrate support assembly 210.

In one embodiment, lift pins 150 of a uniform length may be utilized in cooperation with bumps or plateaus 182 positioned beneath the outer lift pins 150, so that the outer lift pins 150 are actuated before and displace the substrate 140 a greater distance from the upper surface 134 than the inner lift pins 150. In another embodiment, the lift pins 150 may be of varying lengths and are utilized so that they come into contact with the bottom 108 and are actuated through the substrate support assembly 210 at different times. For example, the lift pins 150 that are spaced around the outer edges of the substrate 140, combined with relatively shorter lift pins 150 spaced inwardly from the outer edges toward the center of the substrate 140, allow the substrate 140 to be first lifted from its outer edges relative to its center. Alternatively, the chamber bottom 108 may comprise grooves or trenches positioned beneath the inner lift pins 150, so that the inner lift pins 150 are actuated after and displaced a shorter distance than the outer lift pins 150. Embodiments of a system having lift pins configured to lift a substrate in an edge to center manner from a substrate support assembly that may be used with the invention are described in U.S. Pat. No. 6,676,761, filed Dec. 2, 2002, entitled “Method and Apparatus for Dechucking a Substrate,” and described in U.S. patent application Ser. No. 10/460,916, filed Jun. 12, 2003, entitled “RF Current Return Path for a Large Area Substrate Plasma Reactor,” both of which are hereby incorporated by reference insofar as they teach the coordinated use of lift pins.

The substrate 140 may be moved in and out of the chamber 100 by means of a large handler blade (not shown) which may transfer the substrate 140 between a separate transfer chamber (not shown) and various processing chambers. The substrate 140 enters and exits the chamber 100 through a port (not shown) that also isolates the chamber 100 environment during substrate processing. It is to be understood that the substrate fabrication process involves multiple steps, and that different steps are typically conducted in different chambers that mechanically cooperate with the substrate handling blade. It is also to be understood that the substrate support assembly 210 disclosed herein is not limited in application to any particular type of CVD chamber.

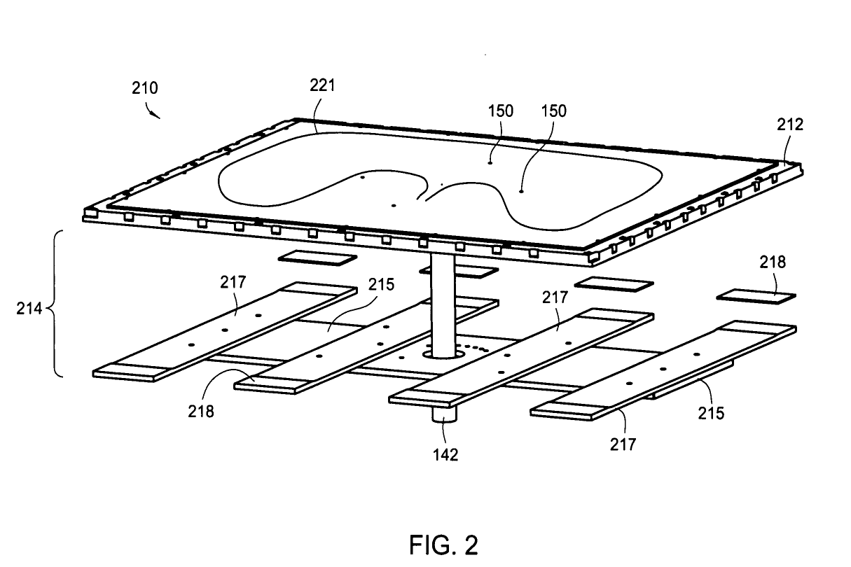

FIG. 2 presents an exploded perspective view of one embodiment of a substrate support assembly 210 configured to support a large-area flat substrate. The substrate support assembly 210 comprises a substrate support 212, such as a susceptor, which defines a generally rectangular surface that exceeds the dimensions of a substrate to be processed, although other geometries and dimensions may be used. Regardless of its shape, it may be desirable that the substrate support 212 and supported substrate be disposed parallel to the gas distribution plate 118 at during processing, with a processing region 112 being defined therebetween.

The substrate support 212 is fabricated from a thermally conductive material such as aluminum and may be coated with a layer of aluminum oxide, and in one embodiment functions as a lower electrode in the chamber 100. The substrate support 212 typically has heating elements 221 within its structure to aid in maintaining the substrate at a desirable processing temperature during plasma enhanced CVD. Electrically conductive wires that provide power for heating the element may be provided through the shaft 142. When the substrate support 212 is fabricated from a material of insufficient strength to support itself during operating conditions such as low pressure and high temperature, heating the substrate support 212 may cause the substrate support 212 to fatigue and deform.

The substrate may be heated during processing to a temperature up to about 460° C. The inventors have noted that under these operating temperature conditions, the substrate support 212 is not rigid, but tends to deform. This deformation of the substrate support was recognized and termed “deflection” in U.S. Pat. No. 6,149,365, issued to Applied Komatsu Technologies, Inc. in 2000. The inventors have also noted that the gas distribution plate 118, which may function as the upper electrode, may also tend to deform due to operating temperature and pressure conditions. The gas distribution plate 118 may be supported along its perimeter, and may have a tendency over time to bow into a convex shape relative to the processing region 112 due to the operating temperature and pressure conditions.

For these reasons, it may be desirable to pre-shape the substrate support 212 to offset thermal and pressure induced deformation in the substrate support 212. This pre-shaping may also be in anticipation of any deformation of the gas distribution plate 118. Pre-shaping may be done either by appropriately varying the thickness of the substrate support 212 at manufacturing, by adjusting the profile of a base structure 214 underneath the substrate support 212, or by pre-shaping the gas distribution plate 118. Ideally, the pre-shape results in the upper electrode or showerhead being parallel relative to the supported substrate at operating conditions.

The substrate support 212 of FIG. 2 includes a base structure 214 under the substrate support 212. The illustrative base structure 214 is non-planar in order to impart a non-planar profile to the substrate support 212 and supported substrate 140. In this embodiment, the base structure 214 is a lattice-type structure having an elongated base support plate 215, and a plurality of lateral support plates 217 disposed generally transverse to the base support plate 215. Although one base support plate 215 and four separate lateral support plates 217 are shown, it is to be under stood that any number of support plates 215, 217 may be used. The one or more base support plates 215 and two or more lateral support plates 217 are preferably fabricated from a material having minimal thermal and electrical conductivity properties. In addition, it is preferred that the plates 215, 217 be fabricated from a material of sufficient strength to retain rigidity under operating temperature and pressure conditions. An example of such a material is ceramic.

It is understood that the substrate support 212 rests immediately on the support plates 215, 217 although the view of FIG. 2 shows the substrate support assembly 210 exploded for purposes of explanation. It is contemplated that the substrate support 212 and support plates 215, 217 do not move relative each other during processing. However, in one chamber 100 arrangement, the shaft 142 is movable vertically so as to permit movement of the substrate support 212 vertically toward and away from the gas distribution plate 118. The shaft 142 also provides a passageway for electrical connectivity to the heating elements 221 in the substrate support 212.

In another embodiment of the substrate support assembly 210, shims 218, such as spacers, are provided along the respective upper surfaces of each of the lateral support plates 217. Preferably, the thickness of the shims 218 is from about 0.4 mm to about 3.5 mm. In this embodiment, the shims 218 are positioned at ends of the lateral support plates 217 however; the shims 218 may be located on other portions of the lateral support plates 217. It is contemplated that the shape of the support plates 217 and/or the use of shims 218 will allow pre-shaping of the substrate support 212 that will translate a desired planar orientation to a substrate during processing as the heated substrate will conform to the planar orientation of the substrate support 212 during processing.

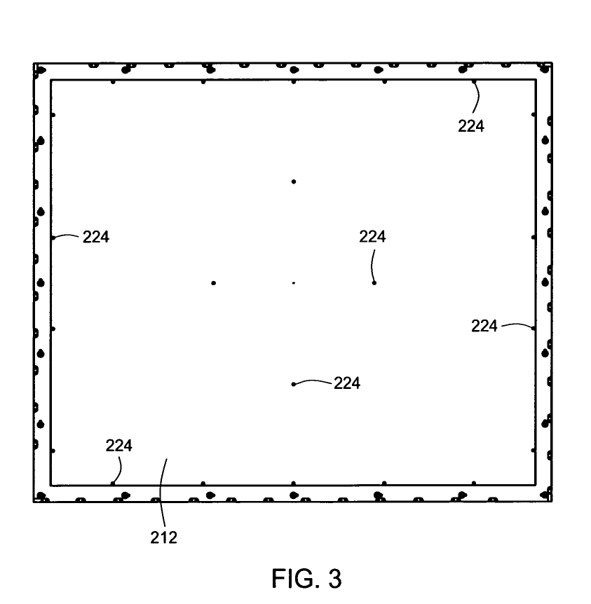

FIG. 3 is a plan view of the substrate support 212 of FIG. 2. The substrate support 212 has a plurality of openings 224 configured to receive the lift pins 150 for lifting the substrate off of the substrate support 212.

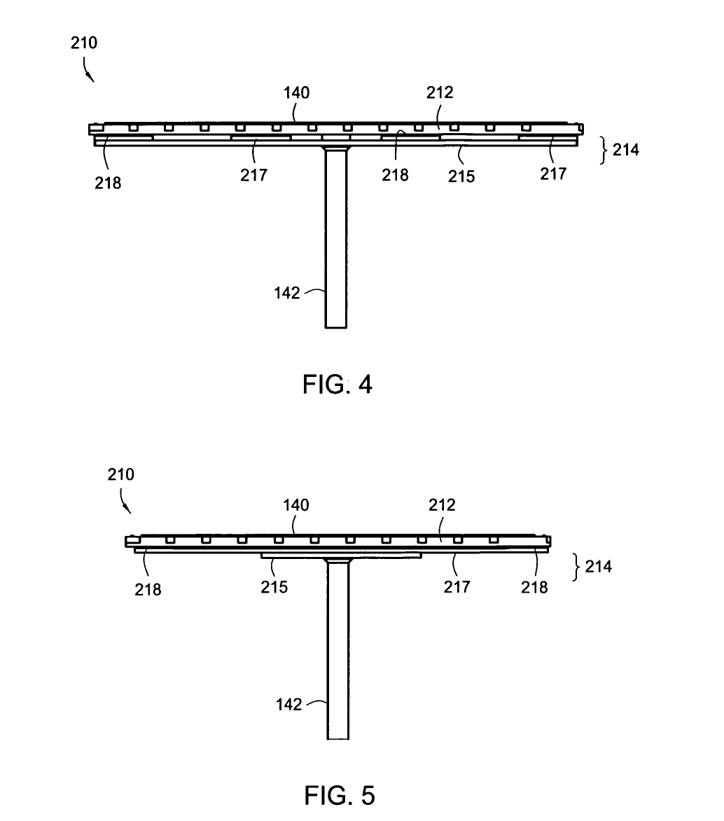

FIG. 4 is a front view of the substrate support assembly 210 of FIG. 2 with the substrate support 212 supported by the base structure 214. A substrate 140 is shown supported by the substrate support 212.

FIG. 5 shows a side view of the substrate support assembly 210 of FIG. 2, with the substrate support 212 supported by the base structure 214. A substrate 140 is shown supported by the substrate support 212.

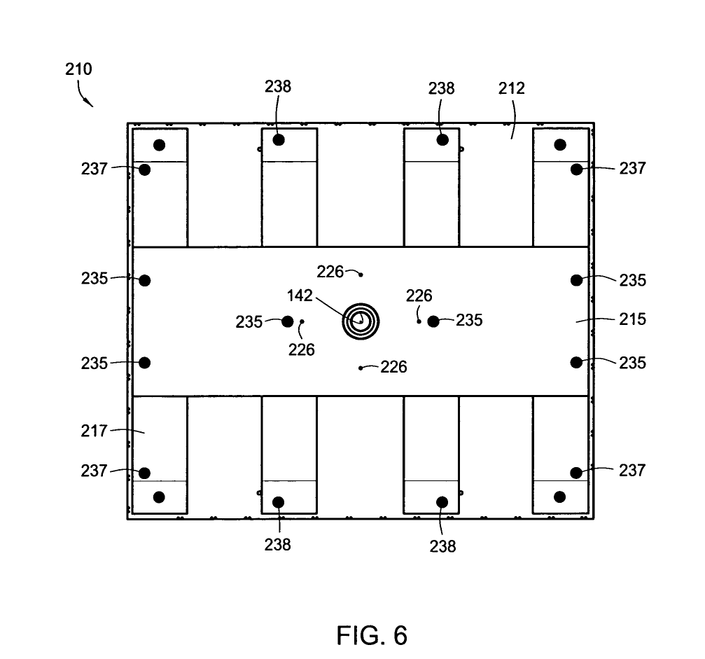

FIG. 6 provides a bottom view of the substrate support assembly 210 of FIG. 2 showing various connectors. First connectors 235 mechanically fasten the base support plate 215 to the respective lateral support plates 217. Connectors 237 optionally mechanically fasten the lateral support plates 217 to the substrate support 212. Connectors, such as pins 238, connect the lateral support plates 217 to respective shims 218. Through-holes 226 in formed through the support plates 215, 217 receive lift pins 150.

When the substrate support 212 is fabricated from a material that is of insufficient strength to rigidly support itself under operating conditions, the substrate support 212 is subject to deformation at points that are not rigidly supported by the base structure 214. In addition, the support plates 215, 217 may experience some slight deformation at operating temperature and pressure over time. When the substrate support 212 endures this deformation, the substrate 140 may deform to comply with the shape of the substrate support 212. The thickness of the base structure 214 and/or the thickness of portions of the substrate support may be varied to overcome this circumstance.

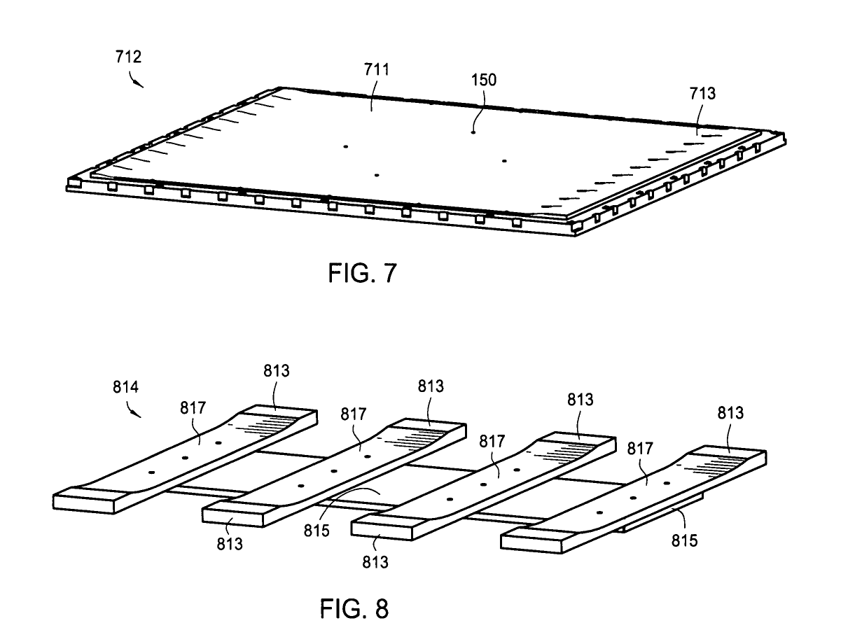

FIG. 7 shows a substrate support 712 which, in one embodiment functions as a lower electrode in the chamber 100. The substrate support 712 is pre-shaped with an upper surface 711 that has a varied thickness. More specifically, the nonplanar substrate support 712 has an increased thickness portion 713 at its edges to form a concave shape. The substrate support 712 is fabricated from a material of insufficient rigidity to support itself at operating conditions which may cause the substrate support 712 to deform and bow over the edges of the relatively rigid base structure 814. Thus, the substrate support 712 is fabricated in a concave shape to anticipate possible thermal and pressure induced deformation of the substrate support 712 and the base structure 814 during processing. It is contemplated that this pre-shaping will translate a desired planar orientation to a substrate during processing as the heated substrate will conform to the planar orientation of the substrate support 712 during processing. It is understood that increased thickness portions 713 may be provided at other selected locations along the substrate support 712.

FIG. 8 shows a base structure 814 having a base support plate 815 and lateral support plates 817 that form a nonplanar integral upper surface. The outer edges of the lateral support members 817 have increased thickness portions 813. The thickness of the increased thickness portions 813 of the plates 817 may be appropriately varied and could be disposed at other locations along the support plates 817.

In another aspect of the present invention, the chamber 100 may have a gas distribution plate 118 that is manufactured in a nonplanar shape. For example, the gas distribution plate 118 may be slightly concave. In this instance, a corresponding convex shape can be given to the substrate support 212. To accomplish this, the base structure 214 may be configured to have limited dimensions such that edges of the substrate support 212 are not fully supported. Thus, some slight bowing of the substrate support 212 into a convex shape may occur at operating conditions. Alternatively, the base structure 214 may be fabricated from a material that likewise allows some slight fatiguing of the plates 217, thereby further permitting bowing of the supported substrate support 212. In either instance, the substrate support 212 is pre-shaped to provide a more parallel orientation between the substrate 140 and the gas distribution plate 118. The extent of bowing can thus be controlled by the profile and material of the base structure 214.

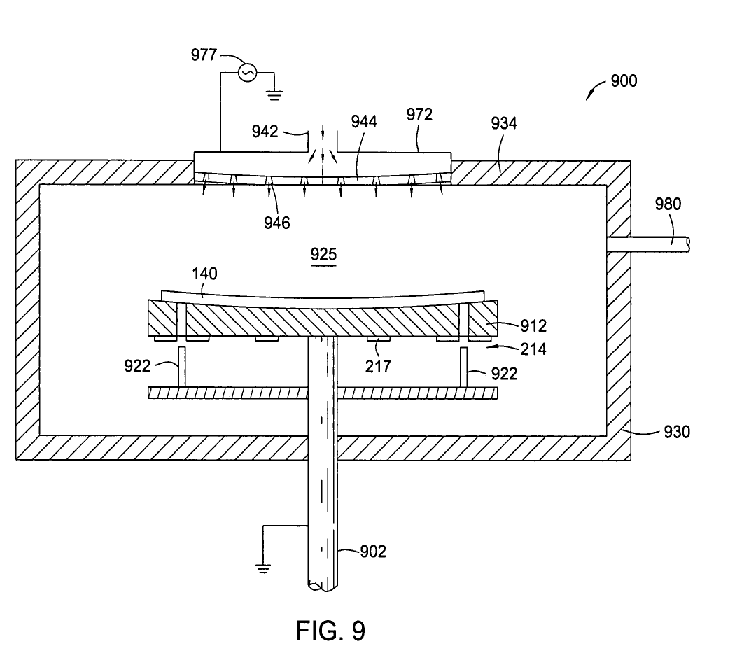

FIG. 9 shows a side, cross-sectional view of a substrate processing chamber 900 in an alternate embodiment. The chamber 900 is again configured to receive a large-area substrate, and to provide a plasma-enhanced chemical vapor deposition (PECVD) on a substrate 140. The chamber 900 includes a side wall 930, a lid 934, a power supply 977, a gas inlet 942, a gas diffusion plate 944 having a plurality of nozzles 946, an exhaust 980, a processing region 925, lift pins 922, an upper electrode 972, a lower electrode 912, and a substrate support shaft 902. When the lower electrode 912 is held at a potential different from that of the upper electrode 972, a plasma can be between the upper electrode 972 and the lower electrode 912.

The gas diffusion plate 944 is shown as nonplanar and in this example is convex; however, the gas diffusion plate 944 may alternately be concave. The gas diffusion plate 944 may be fabricated from 6061 aluminum alloy or other corrosion-resistant material. The lower electrode 912 also functions as a substrate support and has a nonplanar upper surface as well. The nonplanar upper surface may be due to variable thickness in the lower electrode 912, or due to variable configurations of a lattice-type base structure 214. The nonplanar surface of the lower electrode 912 produces a nonplanar profile in the substrate 140. The nonplanar profile of the substrate 140, in turn, generally matches the nonplanar profile of the gas diffusion plate 944. The extent of bowing can again be controlled by the profile and material of the base structure 214. Thus, the substrate 140 and the gas diffusion plate 944 are substantially parallel.

A method is also provided for shaping an electrode in a plasma-enhanced chemical vapor deposition (PECVD) chamber. The method includes the step of providing an upper electrode in the chamber. The method also includes the step of providing a substrate support in the chamber, which may function as a lower electrode, to receive a large-area flat substrate. The substrate support is fabricated from a thermally conductive metal that is of insufficient strength to rigidly support itself under operating conditions. The method also includes the steps of providing a base structure for supporting the substrate support. Preferably, though not required, the base structure of the substrate support is of sufficient strength to rigidly support itself under operating temperature conditions. In one aspect, the substrate support and supported substrate are shaped by providing a nonplanar shape to the base structure. In another aspect, a nonplanar shape of the substrate support is created by providing shims on top of a lattice-type base structure.

In one aspect of the method, the substrate support bows into a substantially planar shape when supported by the base structure under operating conditions. In another aspect, the substrate support bows or is otherwise formed into either a convex or a concave shape when supported by the base structure under operating conditions. In either instance, the substrate support conforms to a shape that is substantially parallel to the upper electrode and/or an upper gas diffusion plate when supported by the base structure under operating conditions. Other selected shapes may include a saddle shape or a cup shape to anticipate deflection in the upper electrode under operating conditions.

In one aspect, the method further comprises the step of providing a nonplanar gas diffusion plate in the chamber above the lower electrode, the plate having a plurality of gas distribution nozzles; and injecting process gas through the nonplanar gas diffusion plate and into a processing region of the chamber. The substrate support conforms to a shape that is substantially parallel to the gas diffuser under operating conditions. In one embodiment, the gas diffuser is convex, and the substrate support bows into the base structure in a concave manner to support the substrate in an orientation that is substantially parallel to the convex gas diffuser.

As can be seen, by appropriately shaping the surface of the electrode upon which is placed the substrate and/or the surface of the opposing electrode, it is possible to produce adequately uniform, useful process results. It is incidentally noted that shaping of the electrode may be used to allow whatever gas present in the chamber that would otherwise be trapped underneath a large substrate in an unpredictable manner to be voided as the substrate is placed on the support electrode. Such haphazardly trapped gas pockets can adversely affect the uniformity of the plasma. Shaping of the electrode may also prevent a substrate that would tend to distort due to temperature non-uniformities from losing physical contact with the substrate support or prevent a substrate with an as-manufactured non-flat shape from never achieving good physical contact to the support electrode.

While the foregoing is directed to embodiments of the present invention, other and further embodiments of the invention may be devised without departing from the basic scope thereof, and the scope thereof is determined by the claims that follow.

1. A plasma-enhanced chemical vapor deposition (PECVD) chamber for processing a large-area substrate, comprising:
an upper electrode; and
a lower electrode which supports the substrate, the lower electrode comprising:
a substrate support fabricated from a material of insufficient strength to rigidly support itself under operating conditions; and
a base structure that is pre-shaped to support the substrate support such that the substrate support deforms to place the substrate in a desired orientation with the upper electrode at operating conditions.

2. The chamber of claim 1, wherein the substrate support is fabricated from a thermally conductive metal, and is configured to receive the substrate.

3. The chamber of claim 2, wherein the substrate support is fabricated from aluminum.

4. The chamber of claim 1, wherein the base structure is pre-shaped in a nonplanar shape to support the substrate support in the desired orientation relative to the upper electrode.

5. The chamber of claim 1, wherein the base structure is fabricated from a material that has sufficient strength to support itself in a substantially rigid orientation under operating conditions.

6. The chamber of claim 4, wherein the base structure is a lattice-type base structure.

7. The chamber of claim 6, wherein the lattice-type base structure comprises at least one ceramic base plate oriented in a first direction, and at least two ceramic support plates disposed on the at least one base plate, and oriented generally transverse to the at least one base plate.

8. The chamber of claim 4, wherein the nonplanar shape of the base structure is created by providing shims at selected locations on a top surface of the base structure.

9. The chamber of claim 1, wherein the substrate support has a variable thickness to provide a nonplanar shape to the substrate support before being exposed to operating conditions.

10. The chamber of claim 9, wherein the substrate support is concave before being placed on the pre-shaped base structure and conforms to the desired orientation after being placed on the base structure under operating conditions.

11. The chamber of claim 1, wherein the substrate support bows into a the desired orientation when supported by the base structure under operating conditions.

12. The chamber of claim 4, wherein the desired orientation is a convex shape relative to the upper electrode when supported by the base structure under operating conditions.

13. The chamber of claim 4, wherein the desired orientation is a concave shape relative to the upper electrode when supported by the base structure under operating conditions.

14. The chamber of claim 1, wherein the upper electrode is one of concave or convex relative to a substantially planar supported substrate.

15. The chamber of claim 1, wherein the chamber further comprises:
a gas diffuser adjacent the lower electrode that is nonplanar; and
the substrate support and supported substrate conforms to desired orientation relative the gas diffuser under operating conditions.

16. The chamber of claim 15, wherein the gas diffuser is a concave shape and the desired orientation is a convex shape.

17. A substrate support assembly for supporting a large-area substrate in a plasma-enhanced chemical vapor deposition (PECVD) chamber, the chamber having an upper electrode, and the substrate support assembly comprising:
(a) a substrate support serving as a lower electrode, the substrate support:
being fabricated substantially from a thermally conductive metal,
being configured to receive the substrate, and
having a shape that compensates for thermal and pressure induced planarity changes of the substrate support during substrate processing; and
(b) a base structure for supporting the substrate support, the base structure having sufficient strength to rigidly support itself under operating conditions.

18. The substrate support assembly of claim 17, wherein the base structure comprises at least one ceramic base plate oriented in a first direction, and at least two ceramic support plates disposed on the at least one base plate and oriented generally transverse to the at least one base plate.

19. The substrate support assembly of claim 18, wherein the substrate support and supported substrate are oriented in a manner that is substantially parallel to the upper electrode under operating conditions.

20. The substrate support assembly of claim 19, wherein the planarity of the substrate support and supported substrate is further affected under operating conditions by modifying the planarity of the base structure.

21. A method of shaping an electrode in a plasma-enhanced chemical vapor deposition (PECVD) chamber, comprising the steps of:
providing an upper electrode in the chamber;
providing a substrate support in the chamber to receive a large-area substrate and to serve as a lower electrode in the chamber, the substrate support being fabricated from a thermally conductive metal of insufficient strength to rigidly support itself under operating conditions; and
providing a base structure for supporting the substrate support that is fabricated from a material that has sufficient strength to rigidly support itself under operating conditions, and that is pre-shaped to support the substrate support and supported substrate such that the substrate support deforms to place the substrate in a desired orientation with the upper electrode at operating conditions.

22. The method of claim 21, wherein the base structure is a lattice-type structure comprising at least one ceramic base plate oriented in a first direction, and at least two ceramic support plates disposed on the at least one base plate and oriented generally transverse to the at least one base plate.

23. The method of claim 21, wherein the base structure is pre-shaped in a nonplanar shape to support the substrate support and supported substrate in the desired orientation relative to the upper electrode.

24. The method of claim 23, wherein each of the at least two ceramic support plates has at least one shim disposed on the top surface of the support plate at a selected location.

25. The method of claim 23, wherein the substrate support has a variable thickness to provide a nonplanar shape to the substrate support before being exposed to operating conditions.

26. The method of claim 25, wherein the substrate support is concave before being placed on the base structure and substantially planar after being placed on the base structure under operating conditions.

27. The method of claim 25, wherein the substrate support is convex before being placed on the base structure and substantially planar after being placed on the base structure under operating conditions.

28. The method of claim 25, wherein the substrate support and supported substrate bow into a substantially planar shape when supported by the base structure under operating conditions.

29. The method of claim 25, wherein the upper electrode is concave.

30. The method of claim 21:
further comprising the step of providing a nonplanar gas diffusion plate in the chamber above the lower electrode, the plate having a plurality of gas distribution nozzles; and
injecting process gas through the nonplanar gas diffusion plate and into a processing region of the chamber; and
wherein the substrate support and supported substrate conform to a shape that is substantially parallel to the gas diffuser under operating conditions.

31. The method of claim 20, wherein:
the gas diffuser is convex; and
the desired orientation is concave.

32. A plasma-enhanced chemical vapor deposition (PECVD) chamber for processing a large-area substrate, comprising:
a nonplanar upper electrode;
a substrate support assembly disposed below the upper electrode and supporting the substrate, wherein a processing region is formed between the upper electrode and the substrate support assembly;
a gas diffusion plate for diffusing gases into the processing region and onto the substrate; and
a lower electrode within the substrate support assembly, the lower electrode being shaped to selectively place the supported substrate in a nonplanar profile under operating conditions.

33. The chamber of claim 32, wherein the gas diffusion plate has a nonplanar profile.
